(19) United States
(12) Patent Application Publication
(10) Pub. No.: US 2008/0188020 A1
(43) Pub. Date: Aug. 7, 2008

(54) Method of LED packaging on transparent flexible film

(76) Inventors: Kuo Wei-Min, Danshuei Township (TW); Yang Chien Ching, Yingge Township (TW)

Correspondence Address: PRO-TECHTOR INTERNATIONAL SERVICES, 20775 NORADA CT., SARATOGA, CA, 95070, US

(21) Appl. No.: 11/702,301

(22) Filed: Feb. 5, 2007

(51) Int. Cl. H01L 21/00

(52) U.S. Cl. 438/27; 257/E21.001

(57) ABSTRACT

A method of LED packaging on transparent on transparent flexible film by: depositing transparent ITO on a flexible transparent substrate to form a conducting layer, and then processing the conducting layer to form a circuit pattern, and then bonding LED chips to the circuit pattern, and then molding a lens over the LED chips to form 360° wide view angle LED package. The method has considered voltage and current matching and provides a suitable wire bond function zone for the LED chips, and keeps the gold wires well protected.

### BACKGROUND OF THE INVENTION

1. Field of the Invention

The present invention relates LED packages and more particularly, to a method of LED packaging on transparent flexible film, in which a transparent metal layer is deposited on a flexible transparent substrate and processed into a circuit pattern for the bonding of LED chips.

2. Description of the Related Art

An LED (light emitting diode) is a unique type of semiconductor diode, like a normal diode, it consists of a chip of semiconducting material impregnated, or doped with impurities to create a p-n junction. As in other diodes, current flows easily from the p-side, or anode, to the n-side, or cathode, but not in the reverse direction. Charge-carriers-electrons and electron holes-flow into the junction from electrodes with different voltages. When an electron meets a hole, it falls into a lower energy level, and releases energy in the form of a photon (Wikipedia, the free encyclopedia).

According to a known method of LED packaging, two lead frames are prepared, and then a LED is fixedly fastened to one lead frame by means of an electrically insulative measure, and then gold wires (lead wires) are installed to electrically connect the LED chip to the lead frames. When an electric current of a predetermined voltage is applied to the lead frames, the LED chip is driven to emit light. Further, the lead frames of multiple LED packages may be soldered to a printed circuit board to form a LED lamp. Electric current can be selectively connected to the lead frames of the LED packages of the LED lamp to selectively turn on the LED chips of the LED packages. Because the printed circuit board does not admit light, the light of the LED chips of the LED packages is not highly visible from the back side of the printed circuit board, thereby limiting the application of the LED lamp.

### SUMMARY OF THE INVENTION

The present invention has been accomplished under the circumstances in view. It is one object of the present invention to provide method of LED packaging on transparent on transparent flexible film, which uses a flexible transparent substrate to carry a transparent metal layer for processing into a circuit pattern for the bonding and packaging of LED chips, thereby increasing the value of the LED package.

The method of LED packaging on transparent on transparent flexible film includes a first step of: depositing a transparent metal layer, for example, ITO (indium tin oxide) on a flexible transparent substrate by spattering to form a conducting layer, a second step of processing the conducting layer into a predetermined circuit pattern by means of a photolithography or laser technique, a third step of using conducting silver paste and employing screen printing and electroplating techniques to form a predetermined wire bond function zone and a power connection function zone on the patterned conducting layer and to form an insulative protective layer, a fourth step of electroplating a layer of soft gold or electroless plating a layer of nickel-gold=subject to a predetermined pattern for the wire bonding of LED chips, a fifth step of bonding LED chips to the wire bond function zone with silver glue and then using gold wires to connect the electrodes of the LED chips, a sixth step of putting a mold on the conducting layer and then filling epoxy resin into the mold to form a condensing or dispersing lens and then removing the mold after molding of the lens. When positive voltage and negative voltage are respectively connected to the electrodes of the LED chips, the LED chips are driven to emit light through 360°.

### BRIEF DESCRIPTION OF THE DRAWINGS

FIG. 1 is a schematic drawing showing a transparent conducting layer deposited on a flexible transparent substrate according to the present invention.

FIG. 2 corresponds to FIG. 1, showing the transparent conducting layer processed into a circuit pattern.

FIG. 3 corresponds to FIG. 2, showing a wire bond function zone and a power connection function zone formed on the patterned conducting layer.

FIG. 4 corresponds to FIG. 3 showing a protective layer formed.

FIG. 5 corresponds to FIG. 4, showing a layer of soft gold electroplated.

FIG. 6 corresponds to FIG. 5, showing a LED chip bonded.

FIG. 7 corresponds to FIG. 6, showing golf wires connected to the electrodes of the LED chip.

FIG. 8 corresponds to FIG. 7, showing a mold mounted on the conducting layer.

FIG. 9 corresponds to FIG. 8, showing a lens of epoxy resin molded in the mold on the conducting layer.

FIG. 10 is a finished product of the present invention.

### DETAILED DESCRIPTION OF THE PREFERRED EMBODIMENT

A method of LED packaging on transparent on transparent flexible film in accordance with the present invention includes the steps of:

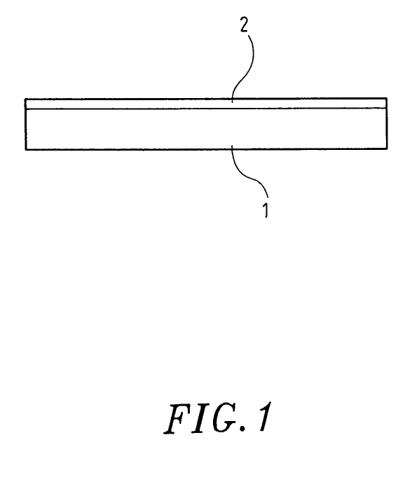

1. Depositing a transparent metal layer, for example, ITO (indium tin oxide) on a flexible transparent substrate (for example, polyethylene terephthalate substrate or polyimide substrate) 1 by spattering to form a conducting layer 2 (see FIG. 1);

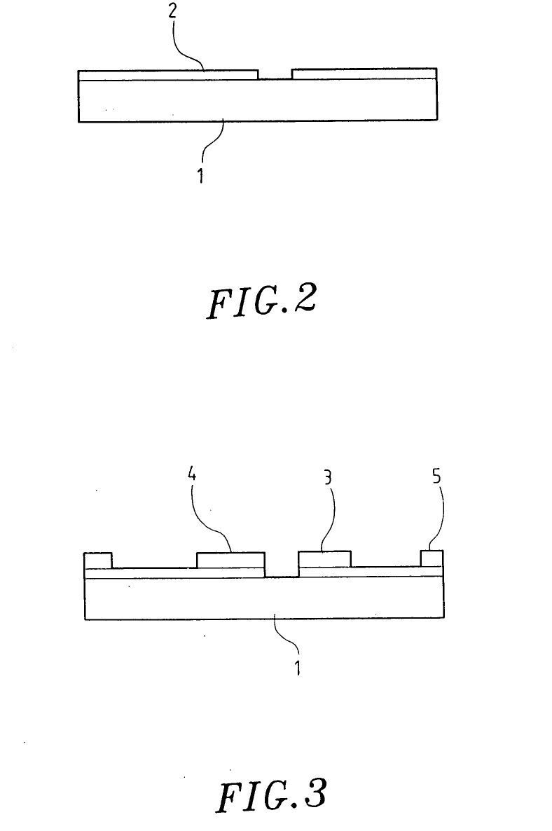

2. Processing the conducting layer 2 into a predetermined circuit pattern by means of a photolithography or laser technique (see FIG. 2);

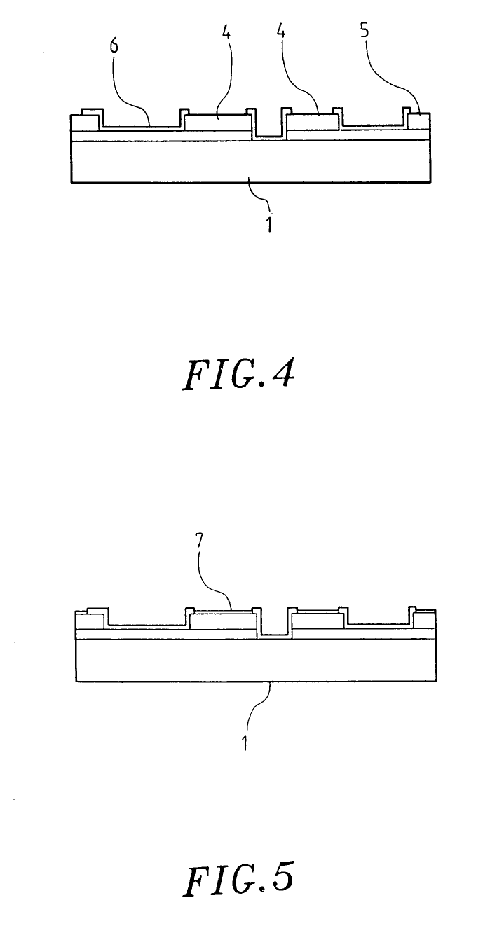

3. Using conducting silver paste and employing screen printing and electroplating techniques to form a wire bond function zone 4 and a power connection function zone 5 on the patterned conducting layer 2 (see FIG. 3) and to form an insulative protective layer 6 (see FIG. 4);

4. Electroplating a layer of soft gold 7 (or electroless plating a layer of nickel-gold) subject to a predetermined pattern for the wire bonding of LED chips (see FIG. 5);

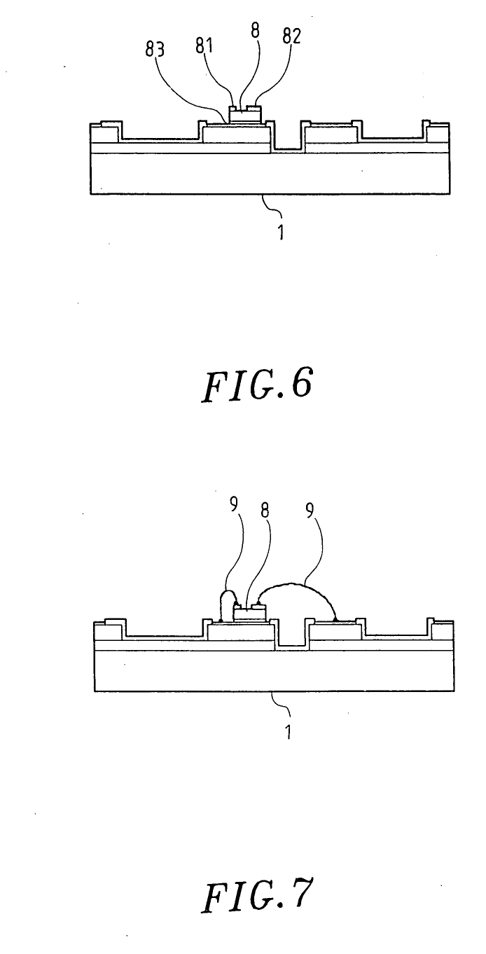

5. Bonding LED chips 8 to the wire bond function zone 4 with silver glue 83 and then using gold wires 9 to connect the electrodes 81 and 82 of the LED chips 8 (see FIGS. 6 and 7);

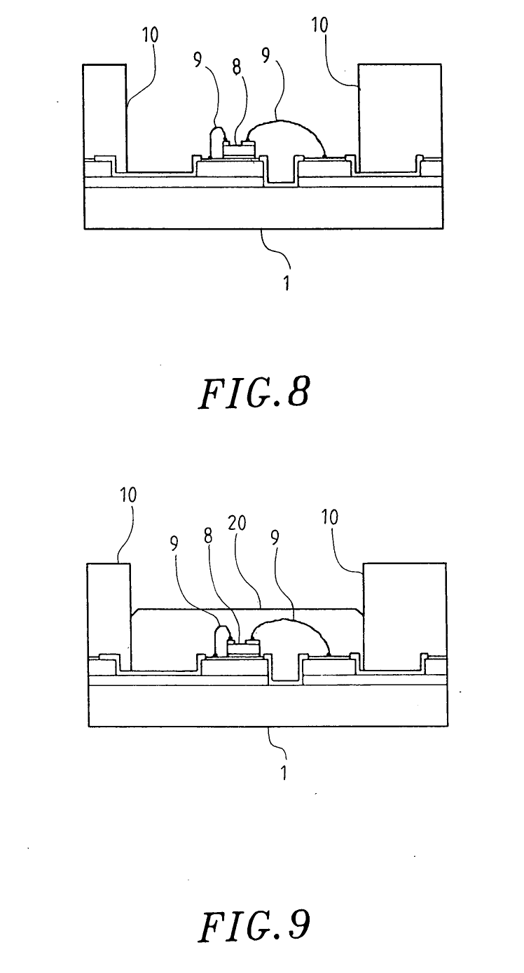

6. Putting a mold 10 on the conducting layer, and then filling epoxy resin into the mold 10 to form a condensing or dispersing lens 20 (see FIGS. 8 and 9); and

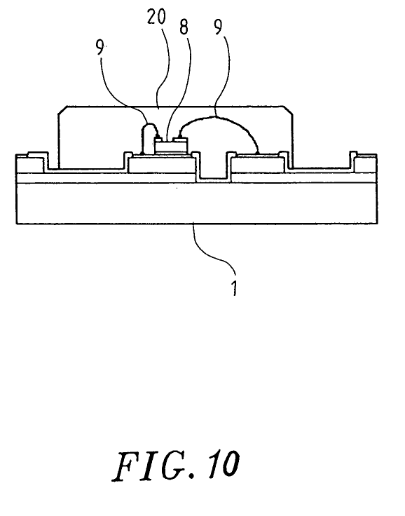

7. Removing the mold 10 so that a LED package is thus obtained (see FIG. 10).

The gold wires 9 of the LED package are well protected by the lens 20. When the LED chips 8 are driven to emit light, the light of the LED package goes through the lens 20 through 360°.

As stated above, the substrate of the LED package is a transparent substrate. Therefore, the LED package is suitable for penetrative application. When positive voltage and negative voltage are respectively connected to the electrodes 81 and 82 of the LED chips 8, the LED chips 8 are driven to emit light through 360°. Further, the LED chips 8 can be so arranged to show to show a pattern so that a pattern of light is seen from any angle when the LED chips 8 are electrically connected.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A method of LED packaging on transparent on transparent flexible film, comprising the steps of:
(a) depositing a transparent metal layer on a flexible transparent substrate by sputtering deposition to form a conducting layer;
(b) processing the conducting layer into a predetermined circuit pattern;
(c) forming a predetermined wire bond function zone and a power connection function zone on the patterned conducting layer and forming an insulative protective layer;
(d) electroplating a layer of soft gold subject to a predetermined pattern for the wire bonding of a LED chip;
(e) bonding LED chips to the wire bond function zone and then using gold wires to connect electrodes of the LED chips; and
(f) using a mold to mold a lens on the conducting layer with epoxy resin.

2. The method of LED packaging on transparent on transparent flexible film as claimed in claim 1, wherein said flexible transparent substrate is selected from one of the materials of polyethylene terephthalate and polyimide.

3. The method of LED packaging on transparent on transparent flexible film as claimed in claim 1, wherein said transparent metal layer is prepared from ITO (indium tin oxide).

4. The method of LED packaging on transparent on transparent flexible film as claimed in claim 1, wherein said conducting layer is processed into said predetermined circuit pattern by means of a photolithography or laser technique.

5. The method of LED packaging on transparent on transparent flexible film as claimed in claim 1, wherein said wire bond function zone and said power connection function zone are formed by using conducting silver paste and employing screen printing and electroplating techniques.

6. The method of LED packaging on transparent on transparent flexible film as claimed in claim 1, wherein said LED chips are bonded to said wire bonding zone with silver glue.
